(19) United States
(12) Patent Application Publication
(10) Pub. No.: US 2024/0206304 A1
(43) Pub. Date: Jun. 20, 2024

(54) ORORGANIC LIGHT-EMITTING ELEMENT FOR LIGHTING AND METHOD FOR MANUFACTURING SAME

(71) Applicant: LOTI CO., LTD., Hwaseong-si, Gyeonggi-do (KR)

(72) Inventors: Woobin IM, Chungcheongnam-do (KR); Jaehoan JEON, Incheon (KR); Jungeun SEO, Daejeon (KR)

(73) Assignee: LOTI CO., LTD., Hwaseong-si, Gyeonggi-do (KR)

(21) Appl. No.: 18/287,026

(22) PCT Filed: Apr. 15, 2022
(86) PCT No.: PCT/KR2022/005459

§ 371 Date: Oct. 16, 2023

(30) Foreign Application Priority Data
Jun. 11, 2021 (KR) 10-2021-0075775

(51) Int. Cl. H10K 59/88; H10K 71/13; H10K 71/60; H10K 102/00

(52) U.S. Cl. CPC H10K 59/88; H10K 71/135; H10K 71/611; H10K 2102/311

(57) ABSTRACT

Provided are a light-emitting element for lighting that is manufactured while being supplied in a roll form, including: a substrate that is wound/unwound on a roll, on which a deposition material is to be deposited with a pattern; gap maintaining protrusions that protrude at a plurality of positions on one surface of the substrate, and are configured to protect the deposition material while contacting the other surface of the substrate when the substrate is wound and unwound on the roll; an insulating layer that is disposed on the one surface of the substrate and is formed by stacking an insulating material; and at least one deposition layer that is formed by depositing at least one deposition material on the one surface of the insulating layer, in which the gap maintaining protrusions have a protrusion height greater than a height of the deposition layer, and a method for manufacturing the same.

### TECHNICAL FIELD

The present invention relates to an organic light-emitting element for lighting and a method for manufacturing the same, and more specifically, to an organic light-emitting element capable of improving structure and quality of a substrate of the organic light-emitting element by preventing contact with a deposition surface subjected to repetitive winding and unwinding, and a method for manufacturing the same.

### BACKGROUND ART

In general, an organic light-emitting element is a self-luminous element that generates light by recombining electron-holes in an organic light-emitting layer.

In a case where current is applied to such an organic light-emitting diode, molecular excitons recombined inside a light-emitting layer exist in two forms of singlet excitons and triplet excitons. Here, 25% of molecular excitons with a high energy state correspond to the singlet excitons, and 75% of molecular excitons with a low energy state correspond to the triplet excitons. The singlet excitons and the triplet excitons return to a ground state with low energy to generate light (photons) or radiate heat, to then be annihilated. Here, a case where light is generated by the singlet excitons is called fluorescence, and a case where light is generated by the triplet excitons is called phosphorescence.

In the case of fluorescent organic materials, only 25% of excitons contribute to generation of light, and in the case of phosphorescent organic materials, light is generated by 75% of the triplet excitons. The remaining 25% of singlet excitons also contribute to the generation of light as energy is transferred to triplet excitons through an ISC (intersystem crossing) path, so that 100% of the excitons contribute to the energy of light.

Since its implementation in 1987, organic light-emitting elements have made rapid progress through development of deposits, development of organic materials, improvement of charge transport, improvement of transparent electrodes, and development of light extraction structures, and commercialized products are appearing in the display and lighting fields. In particular, as the use of incandescent lamps and fluorescent lamps is regulated due to recent energy saving measures, organic light-emitting element light sources are attracting attention.

Further, the organic light-emitting element light sources do not use heavy metals such as mercury or lead, which shows the advantage of being environmentally friendly.

Vacuum deposition and coating methods are generally known as methods for manufacturing such organic light-emitting elements. Here, the vacuum deposition method has been widely used in consideration of the advantages of increase in the purity of constituent layer forming materials and production of long-life organic light-emitting elements.

In the vacuum deposition method, a constituent layer is formed by performing deposition using a deposition source provided at a position opposite to a substrate in a vacuum chamber. In such an existing organic light-emitting element manufacturing process, a large-sized flat glass substrate is used to increase the sizes of equipment and clean rooms, which results in increase in the manufacturing cost.

Since price competitiveness is important in the field of lighting products, it is necessary to produce a large amount of products in a small clean room.

Accordingly, a roll process capable of improving a usable capacity of a clean room by improving production speed with small-sized equipment has been developed.

The roll process refers to a process of forming a constituent layer on the substrate by deposition while unwinding a substrate that is wound in a roll form on one side and rewinding the unwound substrate on the other side.

However, this process has the problem of increasing the risk of defects of the constituent layer when the substrate and the deposition surface come into contact with each other while the substrate is being continuously wound and unwound during a manufacturing process of an organic light-emitting element for lighting, which results in quality deterioration.

### DISCLOSURE

### Technical Problem

To solve the above problems, it is an object of the present invention to provide an organic light-emitting element for lighting and a method for manufacturing the same, capable of preventing defects of a deposition layer during winding and unwinding of a substrate on a roll by printing insulating or conductive transparent/color ink according to the type and characteristics of the organic light emitting element on the substrate to form a plurality of protrusions and arranging the protrusions to protrude above a deposition layer to prevent direct contact of the substrate and the deposition layer.

The object of the present invention is not limited to the object mentioned above, and other objects not mentioned may be clearly understood from the description below.

### Technical Solution

In accordance with an aspect of the present invention, there is provided a light-emitting element for lighting that is manufactured while being supplied in a roll form, including: a substrate that is wound/unwound on a roll, on which a deposition material is to be deposited with a pattern; gap maintaining protrusions that protrude at a plurality of positions on one surface of the substrate, and are configured to protect the deposition material while contacting the other surface of the substrate when the substrate is wound and unwound on the roll; an insulating layer that is disposed on the one surface of the substrate and is formed by stacking an insulating material; and at least one deposition layer that is formed by depositing at least one deposition material on the one surface of the insulating layer, in which the gap maintaining protrusions have a protrusion height greater than a height of the deposition layer.

In addition, the gap maintaining protrusions may be formed by printing transparent ink on the one surface of the substrate.

Further, the gap maintaining protrusions may be formed by printing color ink on the one surface of the substrate.

Furthermore, the gap maintaining protrusions may be formed by printing insulating ink on the one surface of the substrate.

In accordance with another aspect of the present invention, there is provided a method for manufacturing an organic light-emitted element for lighting, including the steps of: forming a pattern on a substrate that is supplied in a roll form using laser; performing printing through ink jetting at a plurality of positions on one surface of the substrate that is supplied in the roll form, on which the pattern is formed, to form gap maintaining protrusions; forming an insulating layer on the substrate that is supplied in the roll form, on which the gap maintaining protrusions are formed; forming a deposition layer on the substrate on which the insulating layer is formed by laminating a plurality of masks on the substrate according to deposition characteristics, removing the masks in a state where a deposition surface of the substrate to be irradiated by a deposition source is positioned in a downward direction, and moving the substrate unwound and wound on the roll so that the gap maintaining protrusions contact tension maintaining rollers; and forming an electrode layer on the substrate on which the deposition layer is formed, performing an aging process for the substrate on which the electrode layer is formed, performing an encapsulating process for the substrate subjected to the aging process, and performing a dividing process to complete the process, in which in the forming the gap maintaining protrusions, the protrusion height of the gap maintaining protrusions is set to be greater than a height of the deposition layer.

In addition, in the forming the gap maintaining protrusions, the gap maintaining protrusions may be formed by printing transparent ink on the one surface of the substrate.

Further, in the forming the gap maintaining protrusions, the gap maintaining protrusions may be formed by printing color ink on the one surface of the substrate.

Furthermore, in the forming the gap maintaining protrusions, the gap maintaining protrusions may be formed by printing insulating ink on the one surface of the substrate.

Specific details for achieving the above object will become clear by referring to the embodiments described in detail below along with the attached drawings.

However, the present invention is not limited to the embodiments disclosed below, and may be configured in various different forms, and the present embodiments are intended to ensure that the disclosure of the present invention is complete and that common knowledge in the technical field to which the present invention pertains is provided.

### Advantageous Effects

According to the present invention, it is possible to provide an organic light-emitting element for lighting and a method for manufacturing the same, capable of preventing defects of a deposition layer during winding and unwinding of a substrate on a roll by printing insulating or conductive transparent/color ink according to the type and characteristics of the organic light emitting element on the substrate to form a plurality of protrusions and arranging the protrusions to protrude above a deposition layer to prevent direct contact of the substrate and the deposition layer.

### DESCRIPTION OF DRAWINGS

FIG. 1 is a diagram showing a state in which an organic light-emitting element for lighting according to an embodiment of the present invention is wound on a roll;

FIG. 2 is a diagram showing an enlarged state of a part of the organic light-emitting element for lighting in FIG. 1;

FIG. 3 is a plan view showing a substrate and gap maintaining protrusions, which are main components of the organic light-emitting element for lighting in FIG. 1;

FIG. 4 is a process diagram showing a method for manufacturing an organic light-emitting element for lighting according to an embodiment of the present invention;

FIG. 5 is a diagram showing a pattern forming step in the manufacturing process of the organic light-emitting element for lighting in FIG. 4;

FIG. 6 is a diagram showing a gap maintaining protrusion forming step in the manufacturing process of the organic light-emitting element for lighting in FIG. 4; and

FIG. 7 is a diagram showing a depositing step in the manufacturing process of the organic light-emitting element for lighting in FIG. 4.

### EXPLANATION OF SYMBOLS

10: ORGANIC LIGHT-EMITTING ELEMENT 11: SUBSTRATE
12: GAP MAINTAINING PROTRUSION 13: INSULATING LAYER
14: DEPOSITION LAYER

### BEST MODE

Hereinafter, with reference to the accompanying drawings, embodiments of the present invention will be described in detail so that those skilled in the art can easily implement the present invention. The present invention may be implemented in many different forms and is not limited to the embodiments described herein. In the drawings, for ease of description, parts unrelated to features of the invention are omitted, and similar parts are given similar reference numerals.

Further, in explaining the invention with reference to the drawings, as necessary, components having the same name may be given different reference numbers. In addition, it should be noted that the reference numerals are used for convenience of explanation, and thus, do not limit the concepts, features, and functions of components.

Throughout the specification, when a part is “connected” to another part, this includes not only “direct connection”, but also “electric connection” with a third element being interposed therebetween. In addition, when a part “includes” a certain component, unless specifically stated to the contrary, this means that the part may further include a different component.

Throughout this specification, the term “organic” does not include small-molecule deposition materials usable for fabricating organic optoelectronic elements, but also includes polymeric materials.

The terms “about”, “substantially”, etc. used throughout this specification mean, a case where manufacturing and material tolerances inherent in stated numerical values are presented, the stated numerical values or numerical values close to the stated numerical values, and are used to facilitate understanding of the invention and prevent unfair infringement of the present disclosure. The term “steps of” used throughout the present specification does not mean “steps for”.

Hereinafter, an embodiment of the present invention will be described in detail with reference to the attached drawings.

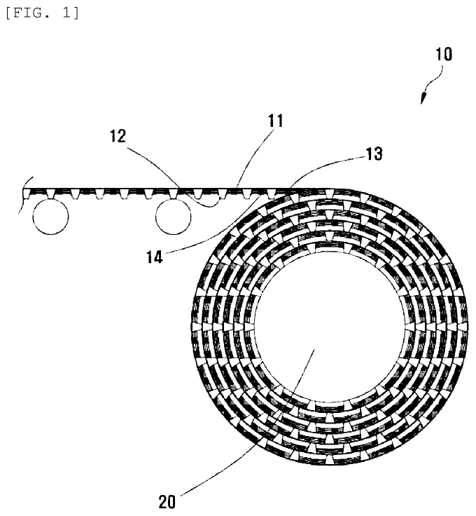

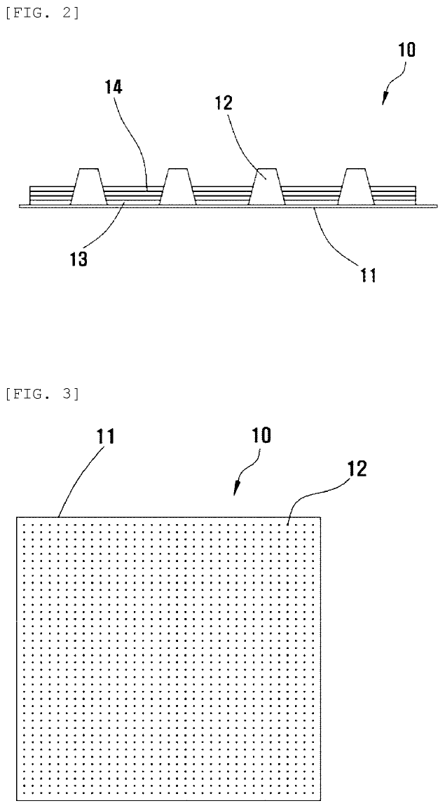

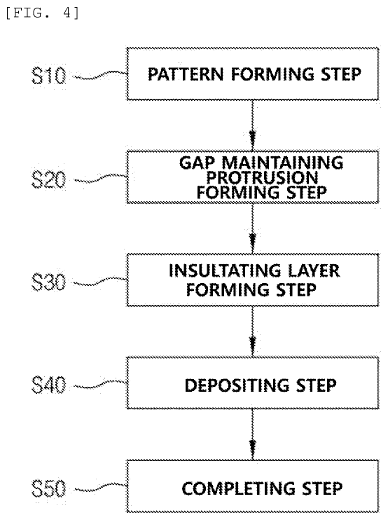

FIG. 1 is a diagram showing a state in which an organic light-emitting element an for lighting according to embodiment of the present invention is wound on a roll, FIG. 2 is a configuration diagram showing an enlarged state of a part of the organic light-emitting element for lighting in FIG. 1, and FIG. 3 is a plan view showing a substrate and gap maintaining protrusions, which are main components of the organic light-emitting element for lighting in FIG. 1.

Referring to FIGS. 1 to 3, an organic light-emitting element 10 for lighting according to an embodiment of the present invention is provided by forming a pattern on a substrate 11 that is moved while being unwound and wound on a roll, forming an insulating layer 13, and then, depositing at least one deposition material layer on the substrate 11 on which the insulating layer 13 is formed, in a state where a film mask suitable for usage is laminated, to form a deposition layer 14. After the deposition, the substrate 11 is separated in a state where moisture is removed and exposure to oxygen is prevented to complete the process.

Here, the deposition material that forms the deposition layer 14 may be an organic material, an electrode material, or the like. In the case of the organic material, an organic deposition layer is formed, and in the case of the electrode material, an electrode layer is formed. It is obvious to those skilled in the art that the organic light-emitting element 10 may be modified into various forms according to usage.

Here, it is desirable to prevent defects from occurring due to direct contact of the substrate and the deposition surface during winding and unwinding on the roll 20 in the deposition process.

To this end, the organic light-emitting element 10 for lighting according to the present embodiment includes the substrate 11, gap maintaining protrusions 12, the insulating layer 13, and the deposition layer 14.

Here, the organic light-emitting element 10 for lighting may be provided with a plurality of the deposition layers 14 made of various materials as necessary.

The substrate 11 is provided to be wound and unwound on the roll 20, on which the deposition material is deposited with a pattern.

Here, the substrate 11 may be a glass substrate or a film, but the invention is not limited thereto.

The gap maintaining protrusions 12 protrude at a plurality of positions on one surface of the substrate 11 where the deposition layer 14 is formed, and contact the other surface of the substrate 11 when the substrate 11 is wound and unwound on the roll to protect the deposition material.

The gap maintaining protrusions 12 are formed by printing through ink jetting to form protrusions that protrude at a plurality of positions on one surface of the substrate 11.

In this case, the gap maintaining protrusions 12 may be formed of transparent ink to prevent scattering or distortion of light emission in consideration of the type and characteristics of the substrate 11.

Further, the gap maintaining protrusion 12 may be formed of color ink having the same color as in the light-emitting element in consideration of the type and characteristics of the substrate 11.

In addition, the gap maintaining protrusion 12 may be formed of insulating ink made of an insulating material that blocks the flow of current in consideration of the type and characteristics of the substrate 11.

In other words, the gap maintaining protrusion 12 may selectively employ the transparency, color, and insulating performance in consideration of the type and characteristics of the substrate 11 such as its usage or type, and the number and characteristics of the deposition layers 14.

Here, the protrusion height of the gap maintaining protrusion 12 is set to be greater than the height of the deposition layer 14, to thereby protect the deposition layer 14 while contacting the opposite surface of the substrate 11 when wound.

The insulating layer 13 is formed on one surface of the substrate 11, and is made of an insulating material.

The deposition layer 14 is formed on one surface of the substrate 11, and is provided by depositing at least one deposition material on the substrate 11.

Here, the deposition material that forms the deposition layer 14 may be an organic material, an electrode material, or the like. In the case of the organic material, an organic deposition layer is formed, and in the case of the electrode material, an electrode layer is formed. It is obvious to those skilled in the art that the organic light-emitting element 10 may be modified into various forms according to usage.

As described above, as the deposition layer 14 is provided as one or more layers depending on the type and characteristics of the substrate 11 while continuously moving to a position where each layer is to be formed, it is possible to prevent defects of the deposition layer 14 due to contact with the substrate using the gap maintaining protrusions 12.

FIG. 4 is a process diagram showing a method for manufacturing an organic light-emitting element for lighting according to an embodiment of the present invention.

Referring to FIG. 4, according to the method for manufacturing the organic light-emitting element for lighting according to the present embodiment, there is provided an organic light-emitting element for lighting in which a deposition surface is positioned downwards to be deposited by a deposition source on a deposition surface of a substrate on which a plurality of gap maintaining protrusions 12 are formed, and thus, the deposition layer 14 is protected by forming a gap between the gap maintaining protrusions 12 and an opposite surface of the substrate 11 when the gap maintaining protrusions 12 contact the opposite surface of the substrate 11 during winding on a roll, thereby minimizing defects of the deposition layer 14 to improve quality.

To this end, the method for manufacturing the organic light-emitting element for lighting includes a pattern forming step S10, a gap maintaining protrusion forming step S20, an insulating layer forming step S30, a depositing step S40, and a completing step S50.

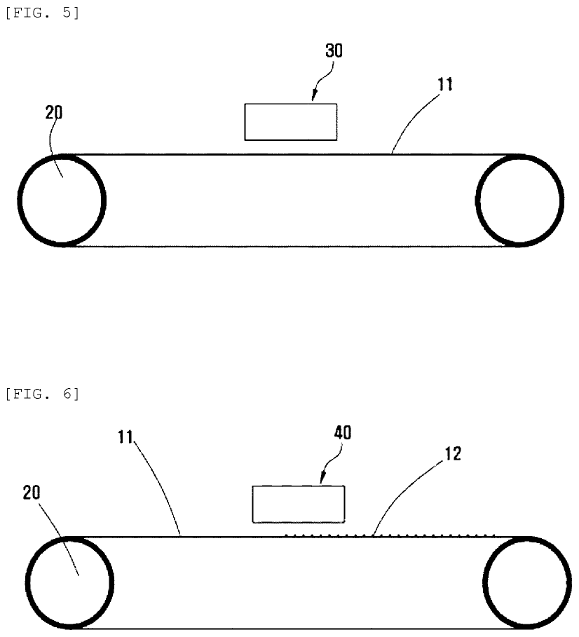

FIG. 5 is a diagram showing a pattern forming step in the manufacturing process of the organic light-emitting element for lighting in FIG. 4.

Referring to FIG. 5, in the pattern forming step S10, a pattern is formed on a substrate that is supplied in a roll form using laser.

In the pattern forming step S10, a pattern according to the type and characteristics of the organic light-emitting element is formed on the substrate 11 that has undergone laminating and sputtering which are preprocessing, using a laser patterning device 30.

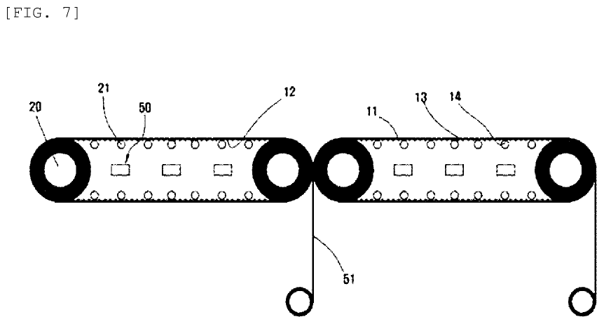

FIG. 6 is a diagram showing a gap maintaining protrusion forming step in the manufacturing process of the organic light-emitting element for lighting in FIG. 4.

Referring to FIG. 6, in the gap maintaining protrusion forming step S20, printing is performed through ink jetting at a plurality of positions on one surface of the substrate 11 that is supplied from the roll 20, on which the pattern is formed, to form gap maintaining protrusions 12.

That is, in order to protect the deposition surface of the substrate 11, printing is performed so that the protrusions are formed by ink jetting from the printer 40 at a plurality of positions, thereby preventing contact defects.

Here, in the gap maintaining protrusion forming step S20, the protrusion height of the gap maintaining protrusions 12 is greater than the height of the deposition layer 14 to prevent contact.

Here, in the gap maintaining protrusion forming step S20, the gap maintaining protrusions 12 may be formed by printing transparent ink on one surface of the substrate 11.

Alternatively, in the gap maintaining protrusion forming step S20, the gap maintaining protrusions 12 may be formed by printing color ink on one surface of the substrate 11.

In addition, in the gap maintaining protrusion forming step S20, the gap maintaining protrusions 12 may be formed by printing insulating ink on one surface of the substrate 11.

In other words, the gap maintaining protrusions 12 may be selectively formed for transparency, color, and insulation, in consideration of the usage, type, and characteristics of the substrate 11 and the number and characteristics of the deposition layers 14.

That is, the gap maintaining protrusions 12 may be selectively made of a material that protects the deposition layer 14 while preventing scattering or distortion of light when the organic light-emitting element 10 emits light.

In the insulating layer forming step S30, an insulating layer is formed on the substrate that is supplied in the roll from, on which the gap maintaining protrusions 12 are formed.

FIG. 7 is a diagram showing a depositing step in the manufacturing process of the organic light-emitting element for lighting in FIG. 4.

Referring to FIG. 7, in the depositing step S40, in order to form the deposition layer 14, a deposition material is deposited on the substrate on which the insulating layer 13 is formed by laminating a plurality of masks 51 on the substrate according to deposition characteristics, removing the masks in a state where a deposition surface of the substrate to be irradiated by a deposition source 50 is positioned in a downward direction, and moving the substrate 11 wound and unwound on the rolls 20 so that the gap maintenance protrusions 12 contact a plurality of tension maintaining rollers 21 provided at a plurality of positions. Here, an encapsulating process of encapsulating at least one mask 51 selected according to the type and characteristics of the deposition layer 14 to be formed on the substrate 11 is first performed, and then, the deposition is performed while the substrate 11 is moving in a state where the deposition surface of the substrate is positioned downwards according to the position of the deposition source 50 positioned below and the gap maintaining protrusions 12 contact the rolls 20 and the tension maintaining rollers 21.

In this way, in the depositing step S40, in a case where the substrate moves with the deposition surface of the substrate 11 directed downwards, it is possible to prevent damages of the deposition surface by the gap maintaining protrusions 12 that contact the plurality of tension maintaining rollers 21, and as the deposition material is positioned in the gap created between the gap maintaining protrusions 12 and the surface of the substrate opposite to the deposition surface, it is possible to prevent defects of the substrate 11 when wound and unwound, thereby improving quality.

Here, the deposition material that forms the deposition layer 14 may be an organic material, an electrode material, or the like. In the case of the organic material, an organic deposition layer is formed, and in the case of the electrode material, an electrode layer is formed. It is obvious to those skilled in the art that the organic light-emitting element 10 may be modified into various forms according to usage.

In the completing step S50, an electrode layer is formed on the substrate 11 on which the deposition layer 14 is formed, an aging processing for the substrate on which the electrode layer is formed is performed, an encapsulation process is performed for the substrate subjected to the aging process, and then, a dividing process is performed to complete the process.

Here, the electrode layer deposited on the substrate includes both of a transparent electrode and an opaque electrode.

After the electrode layer is formed, the aging process for vacuum-drying the substrate is performed, the encapsulation process for encapsulating the substrate to preserve the deposit is performed to remove moisture, and then, a post-processing process is performed to prevent oxygen from entering the substrate.

After the post-processing process is completed, the dividing process for cutting the substrate according to the size and type of the organic light-emitting element 10 for lighting is performed.

The above description is merely an illustrative explanation of the technical idea of the present invention, and various modifications and variations will be possible to those skilled in the art without departing from the essential characteristics of the present invention.

Accordingly, the embodiments disclosed in the present specification are not intended to limit the technical idea of the present invention, and the scope of the technical idea of the present invention is not limited by these embodiments.

The scope of protection of the present invention should be interpreted in accordance with claims, and all technical ideas within the equivalent scope should be construed as being included in the scope of the present invention.

1. A light-emitting element for lighting that is manufactured while being supplied in a roll form, comprising:
a substrate that is wound/unwound on a roll, on which a deposition material is to be deposited with a pattern;
gap maintaining protrusions that protrude at a plurality of positions on one surface of the substrate, and are configured to protect the deposition material while contacting the other surface of the substrate when the substrate is wound and unwound on the roll;
an insulating layer that is disposed on the one surface of the substrate and is formed by stacking an insulating material; and
at least one deposition layer that is formed by depositing at least one deposition material on the one surface of the insulating layer,
wherein the gap maintaining protrusions have a protrusion height greater than a height of the deposition layer.

2. The organic light-emitting element according to claim 1, wherein the gap maintaining protrusions are formed by printing transparent ink on the one surface of the substrate.

3. The organic light-emitting element according to claim 1, wherein the gap maintaining protrusions are formed by printing color ink on the one surface of the substrate.

4. The organic light-emitting element according to claim 1, wherein the gap maintaining protrusions are formed by printing insulating ink on the one surface of the substrate.

5. A method for manufacturing an organic light-emitted element for lighting, comprising the steps of:
forming a pattern on a substrate that is supplied in a roll form using laser;
performing printing through ink jetting at a plurality of positions on one surface of the substrate that is supplied in the roll form, on which the pattern is formed, to form gap maintaining protrusions;
forming an insulating layer on the substrate that is supplied in the roll form, on which the gap maintaining protrusions are formed;
forming a deposition layer on the substrate on which the insulating layer is formed by laminating a plurality of masks on the substrate according to deposition characteristics, removing the masks in a state where a deposition surface of the substrate to be irradiated by a deposition source is positioned in a downward direction, and moving the substrate unwound and wound on the roll so that the gap maintaining protrusions contact tension maintaining rollers; and
forming an electrode layer on the substrate on which the deposition layer is formed, performing an aging process for the substrate on which the electrode layer is formed, performing an encapsulating process for the substrate subjected to the aging process, and performing a dividing process to complete the process,
wherein in the forming the gap maintaining protrusions, the protrusion height of the gap maintaining protrusions is set to be greater than a height of the deposition layer.

6. The method according to claim 5, wherein in the forming the gap maintaining protrusions, the gap maintaining protrusions are formed by printing transparent ink on the one surface of the substrate.

7. The method according to claim 5, wherein in the forming the gap maintaining protrusions, the gap maintaining protrusions are formed by printing color ink on the one surface of the substrate.

8. The method according to claim 5, wherein in the forming the gap maintaining protrusions, the gap maintaining protrusions are formed by printing insulating ink on the one surface of the substrate.
